(19) United States
(12) Patent Application Publication
(10) Pub. No.: US 2012/0138274 A1
(43) Pub. Date: Jun. 7, 2012

(54) COOLING APPARATUS FOR ELECTRIC MODULES OF HYBRID ELECTRIC VEHICLE OR ELECTRIC VEHICLE

(75) Inventors: Dong Min Shin, Hwaseong (KR); Woo Yong Jeon, Seoul (KR); Joon Hwan Kim, Seoul (KR); Jin Hwan Jung, Suwon (KR); Min Ji Kim, Hwaseong (KR); Jung Hong Joo, Hwaseong (KR); In Pil Yoo, Seoul (KR)

(73) Assignees: KIA MOTORS CORPORATION, Seoul (KR); HYUNDAI MOTOR COMPANY, Seoul (KR)

(21) Appl. No.: 13/082,921

(22) Filed: Apr. 8, 2011

(30) Foreign Application Priority Data
Dec. 3, 2010 (KR) 10-2010-0122656

(51) Int. Cl. B60K 11/02; H05K 7/20

(52) U.S. Cl. 165/104.28; 165/41; 165/104.33

(57) ABSTRACT

The present invention provides an apparatus for effectively cooling electric modules such as an inverter and an LDC installed in a hybrid electric vehicle or an electric vehicle. The cooling apparatus for electric modules of a hybrid electric vehicle or an electric vehicle secures a uniform cooling efficiency and achieves an excellent heat radiating efficiency at the same time by realizing a new type of cooling system adapted to separately manage heat transfer in the cooling water passages of first and second electric modules by separating an upper passage of the first electric module and a lower passage of the second electric module using a cooling separator.

### CROSS-REFERENCE TO RELATED APPLICATION

This application claims under 35 U.S.C. §119(a) the benefit of Korean Patent Application No. 10-2010-0122656 filed Dec. 3, 2010, the entire contents of which are incorporated herein by reference.

### BACKGROUND

(a) Technical Field

The present disclosure relates to an apparatus for effectively cooling electric modules such as an inverter and a low voltage DC-DC converter (LDC) installed in a hybrid electric vehicle or an electric vehicle.

(b) Background Art

In general, a high voltage battery that is adapted to provide driving power to an electric motor may be incorporated into a hybrid electric vehicle or an electric vehicle, in which case the high voltage battery supplies required to provide electric power while being repeatedly charged and discharged during traveling of the vehicle.

Such a high voltage battery related system is designed as an integrated structure in which several products are assembled into one device and this battery related system is mounted under a back seat in the interior of a vehicle or into a trunk space. The high voltage battery related system typically includes a battery, a low voltage DC-DC converter (LDC), a motor control unit (MCU), and an inverter.

For example, a hybrid electric vehicle or an electric vehicle includes an LDC, i.e., a low voltage DC/DC converter configured to convert the high voltage DC current of the high voltage battery to a low voltage DC current. In this case, the LDC serves to supply the DC current of the high voltage battery by converting it to be suitable to a voltage used in a load of an electric module.

Such a hybrid electric vehicle or electric vehicle requires a high output inverter system for operating an electric motor, wherein the inverter system functions to convert D/C energy of a battery to an A/C current required to drive the motor, in which case researchers are growing more and more interested in heat radiating efficiencies of electric modules as it is necessary to maintain the temperature of an inverter within a limited range where embedded integrated chips (ICs) can endure the temperature in order to maintain the operational state of the inverter system suitably. This is an issue due to a large amount of heat emitted from the inverter system, and thus this often causes problems.

For example, in relation to a conventional cooling apparatus for electric modules of a hybrid electric vehicle, a first electric module (e.g. an LDC) and a second electric module (e.g. an inverter) are stacked from top to bottom and a passage is formed between them along a contact surface of a heat radiating portion in a heat radiating cover.

However, as the first electric module and the second electric module share cooling water and a single passage, the cooling apparatus requires a bypass structure in case of an excessive pressure drop, resulting in lowering of the cooling efficiency of the first electric module. Further, the added heat of the first and second electric modules raises the temperature of cooling water, in turn lowering heat radiating efficiency. That is, when the first electric module and the second electric module share cooling water, and as their heat energy is simultaneously transferred to the cooling water, the temperature of the cooling water rises to a maximum limit or higher, resulting in lowering of heat radiating efficiency. Furthermore, as the passage for radiation of the heat of the first and second electric modules is dependent, the degree of freedom in design lowers as well.

### SUMMARY OF THE DISCLOSURE

The present invention relates to a cooling apparatus for electric modules of a hybrid electric vehicle or an electric vehicle that secures a uniform cooling efficiency while at the same time achieving increased heat radiating efficiency by realizing a new type of cooling system configured to separately manage cooling water passages of first and second electric modules by separating an upper passage of the first electric module and a lower passage of the second electric module using a cooling separator.

In one aspect, the present invention provides a cooling apparatus for electric modules of a hybrid electric vehicle or an electric vehicle, wherein upper and lower cooling water passages are formed on a bottom surface of an upper first electric module and a top surface of a lower second electric module between the first and second electric modules. These first and second electric modules may be longitudinally stacked and communicated with an inlet and an outlet opposite to the inlet. Additionally, the cooling apparatus may include a thin plate shaped cooling separator installed at a border between the first and second cooling water passages to isolate the first and second cooling water passages such that cooling water introduced through the inlet may be branched and flowed through the upper and lower cooling water passages and then discharged through the outlet.

In some embodiments of the present invention, the cooling water separator that is configured to isolate the cooling water passages formed on the surfaces of the first and second electric modules may have a zigzagged shape, which follows the paths of the cooling water passages.

Advantageously, as cooling water for first and second electric modules is separately managed, heat of the cooling water for the first and second electric modules is less interdependent. Thus the cooling efficiencies of the electric modules can be maintained uniformly. Additionally, when a liquid sealant is used in a cooling separator, sealant sludge is prevented from being introduced into cooling water passages to which heat radiating fins are mounted. Therefore the cooling water passages are prevented from becoming blocked. Even further, cooling efficiency can be enhanced by modifying a compact package having a simultaneous cooling structure, increasing product value.

Furthermore, vehicle packaging can be advantageously achieved by maximizing the degree of freedom in heat radiating designs which are not dependent on each other while maintaining compact packaging of a heat radiating unit, and as a drop in system pressure can be lessened, a water pump can be optimized, thus resulting in a reduction in manufacturing costs.

### BRIEF DESCRIPTION OF THE DRAWINGS

The above and other features of the present invention will now be described in detail with reference to certain exemplary embodiments thereof illustrated in the accompanying drawings which are given hereinbelow by way of illustration only, and thus are not limitative of the present invention, and wherein:

FIGS. 1A and 1B are perspective views illustrating a cooling apparatus for electric modules of a hybrid electric vehicle or an electric vehicle according to an exemplary embodiment of the present invention;

FIG. 2 is a sectional view illustrating the cooling apparatus for electric modules of a hybrid electric vehicle or an electric vehicle according to the exemplary embodiment of the present invention;

FIG. 3 is a perspective view illustrating a cooling separator applied to the cooling apparatus for electric modules of a hybrid electric vehicle or an electric vehicle according to the exemplary embodiment of the present invention; and

FIG. 4 is a sectional view illustrating flows of cooling water in the cooling apparatus for electric modules of a hybrid electric vehicle or an electric vehicle according to the exemplary embodiment of the present invention.

### DETAILED DESCRIPTION

Hereinafter, an exemplary embodiment of the present invention will be described below in detail with reference to the accompanying drawings such that those skilled in the art to which the present invention pertains can easily practice the present invention.

It is understood that the term “vehicle” or “vehicular” or other similar terms as used herein is inclusive of motor vehicles in general such as passenger automobiles including sports utility vehicles (SUV), buses, trucks, various commercial vehicles, watercraft including a variety of boats and ships, aircraft, and the like. The present systems will be particularly useful with a wide variety of motor vehicles.

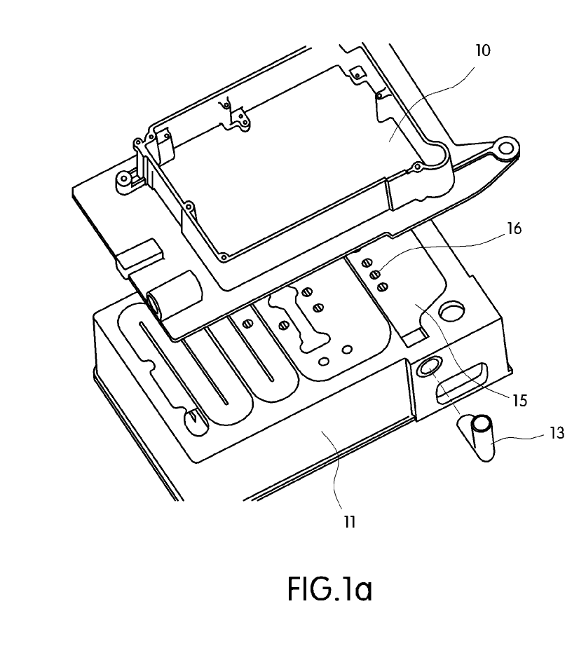

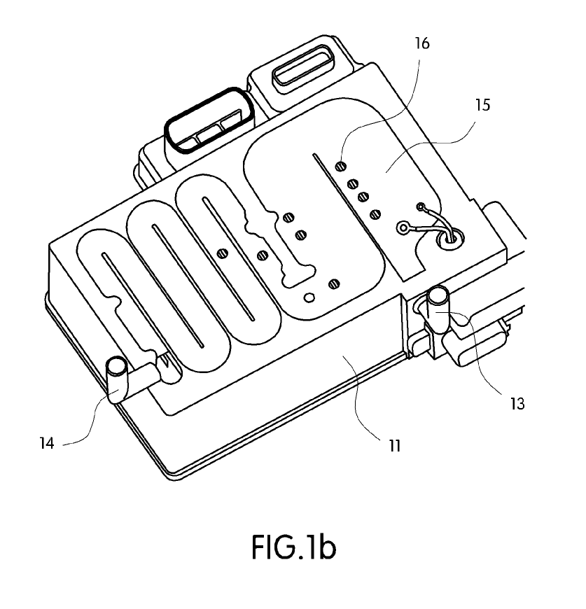

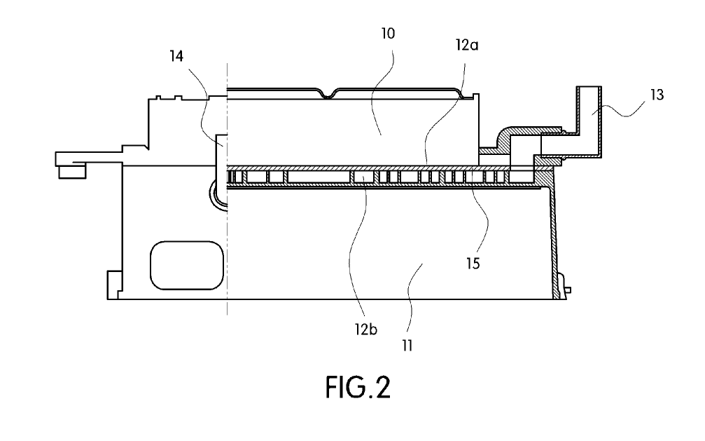

FIGS. 1A and 1B are perspective views illustrating an exemplary cooling apparatus for electric modules of a hybrid electric vehicle or an electric vehicle according to an embodiment of the present invention. FIG. 2 is a sectional view illustrating the exemplary cooling apparatus for electric modules of a hybrid electric vehicle or an electric vehicle according to the exemplary embodiment of the present invention.

As illustrated in FIGS. 1A, 1B and 2, the cooling apparatus has a structure in which cooling water passages 12a and 12b of first and second electric modules 10 and 11 are separately managed to maintain the cooling efficiencies of the electric modules uniformly and enhance the entire heat radiating efficiency of the cooling apparatus.

For this purpose, two electric modules are provided for use in a hybrid electric vehicle or an electric vehicle, for example, a first electric module 10, e.g., an LDC, and a second electric module 11, e.g., an inverter, are assembled from top to bottom and are sealed accordingly.

Illustratively, the first and second modules are embedded within the housings 10 and 11 respectfully. Thus, the first and second electric modules such as an LDC and an inverter will be described in the form of housings.

A cooling water passage 12a which forms a certain path and through which cooling water flows in one direction is formed on the bottom surface of the first electric module 10, and a cooling water passage 12b which forms a certain path and through which cooling water flows in one direction is formed on the top surface of the second electric module 10.

Accordingly, when the first and second electric modules 10 and 11 are longitudinally coupled to each other, the cooling water passages 12a and 12b of the first and second electric modules 10 and 11 face each other longitudinally.

The cooling water passages 12a and 12b are connected with an inlet 13 for introduction of cooling water and an outlet 14 for discharge of cooling water wherein the inlet 13 and the outlet 14 are opposite ends, whereby after cooling water introduced through the inlet 13 performs a cooling operation via the cooling water passages 12a and 12b, the water is discharged to the outside through the outlet 14. Thus, inlet 13 and outlet 14 are in fluid communication with each other.

More specifically, in the present invention, a cooling separator 15 is provided as a means for separately managing the cooling water passage 12a of the first electric module 10 and the cooling water passage 12b of the second electric module 11.

For this purpose, the cooling separator 15 has a thin plate shape and is inserted into a border between the cooling water passage 12a situated on the bottom surface of the first electric module 10 and the cooling water passage 12b situated on the top surface of the second electric module 11. As the cooling separator 15 is installed between the upper and lower cooling water passages 12a and 12b, the upper and lower cooling water passages 12a and 12b are isolated (i.e., separated). Thus the cooling water supplied to the cooling water passages 12a and 12b is allowed to flow separately. That is, the cooling separator 15 can effectively separate the cooling water passages 12a and 12b while maintaining a certain shape.

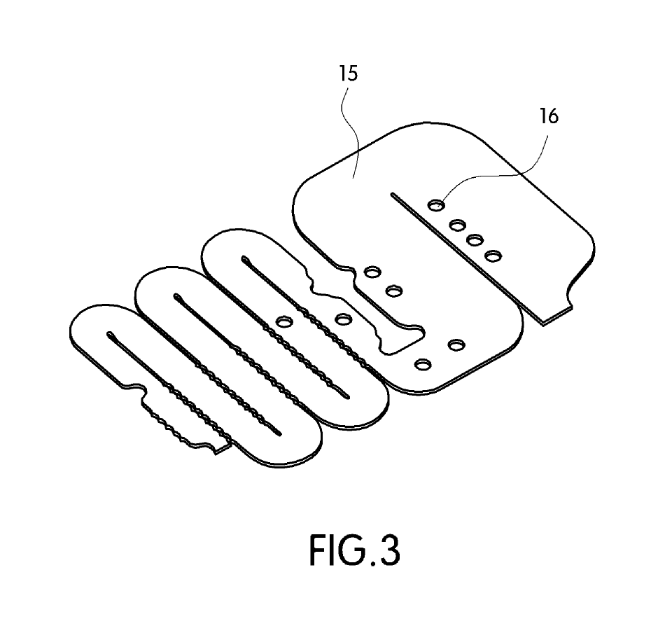

For example, as illustrated in FIG. 3, the cooling separator 15 forms a zigzagged shape utilizing a plurality of bent sections which are alternately repeated while following the shape of a path proceeding from one side to another by the shape of the paths of the cooling water passages 12a and 12b formed on planes of the first and second electric modules 10 and 11.

In some embodiments of the present invention, the cooling separator 15 may be made of a rubber material or a metal material such as stainless steel. By doing so, the cooling separator 15 has corrosion-resistant properties with regards to cooling water, thereby maintaining durability for a long period of time.

More specifically, the cooling separator 15 may also have a plurality of orifices or apertures 16 connecting the upper and lower cooling water passages 12a and 12b at several locations throughout the cooling separator 15. The orifices/apertures 16 applied to the cooling separator 15 can increase cooling efficiency locally and the flux of the cooling water can be controlled by changing the locations of the orifices/apertures 16.

Furthermore, while the cooling separator 15 is a means for separating cooling water passages of electric modules, it can also function as a sealing gasket. That is, as the cooling separator prevents a liquid sealant from being introduced into the cooling water passages, it can also prevent blocking of the cooling water passages by the sealant as well.

For example, a liquid sealant is coated on a flange at a coupling portion of the first and second electric modules and is pressed onto the inside when the first and second electric modules are coupled. In the illustrative embodiment of the present invention, the cooling water passages are covered and finished by the cooling separator, thus preventing the sealant from penetrating into the cooling passages.

Hereinafter, an in-use state of the cooling apparatus for electric modules of a hybrid electric vehicle or an electric vehicle will be described.

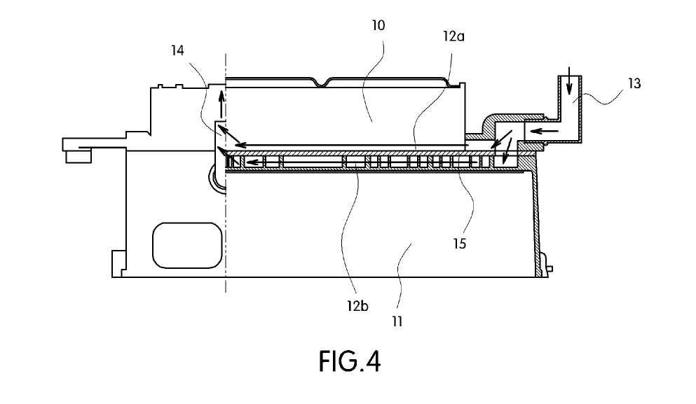

FIG. 4 is a sectional view illustrating flows of cooling water in the exemplary cooling apparatus for electric modules of a hybrid electric vehicle or an electric vehicle according to the exemplary embodiment of the present invention.

As illustrated in FIG. 4, the upper first electric module 10 and the lower second electric module 11 are assembled from top to bottom and the cooling separator 15 is inserted between the cooling water passages 12a and 12b facing each other such that the upper and lower cooling water passages 12a and 12b are separated from each other and in fluid communication with the inlet 13 and the outlet 14.

Thus, if cooling water is introduced through the inlet 13, it flows through the upper cooling water passage 12a and the lower cooling water passage 12b separately to cool the first electric module 10 and the second electric module 11 respectively and then is discharged through the outlet 14. The process is repeated to allow the cooling water flowing through the cooling water passages to cool the first and second electric modules continually and independently.

As described above, as the temperatures of the cooling water in the cooling water passages are individually managed, they are prevented from influencing each others temperature, whereby the cooling apparatus maintains the cooling efficiencies of the electric modules uniformly and enhances the cooling efficiencies of the electric modules.

The invention has been described in detail with reference to an exemplary embodiment thereof. However, it will be appreciated by those skilled in the art that changes may be made in these embodiments without departing from the principles and spirit of the invention, the scope of which is defined in the appended claims and their equivalents. Further, many modifications may be made to specific situations and materials without departing from the essence of the invention. Therefore, the present invention is not limited to the detailed description of the preferred embodiment but includes all embodiments within the scope of the attached claims.

What is claimed is:

1. A cooling apparatus for electric modules of a hybrid electric vehicle or an electric vehicle, wherein upper and lower cooling water passages are formed on a bottom surface of an upper first electric module and a top surface of a lower second electric module between the first and second electric modules, wherein the first and second electric modules being longitudinally stacked and are in fluid communication with an inlet and an outlet opposite to the inlet, the cooling apparatus comprising:
a thin plate shaped cooling separator installed at a border between the first and second cooling water passages to isolate the first and second cooling water passages such that cooling water introduced through the inlet is branched and flowed through the upper and lower cooling water passages and then is discharged through the outlet.

2. The cooling apparatus of claim 1, wherein the thin plate shaped cooling separator is configured to isolate the cooling water passages formed on the surfaces of the first and second electric modules has a zigzagged shape, which follows paths of the cooling water passages.

3. The cooling apparatus of claim 2, wherein a plurality of orifices connecting the upper and lower cooling water passages are formed in the thin plate shaped cooling separator to locally enhance cooling efficiency.

4. The cooling apparatus of claim 1, wherein the thin plate shaped cooling separator is made of one of a group consisting of a rubber material or stainless steel having corrosion-resistant properties with regards to the cooling water.

5. A cooling apparatus for modules of a hybrid electric vehicle or an electric vehicle, wherein upper and lower cooling water passages are formed on a bottom surface of an upper first module and a top surface of a lower second module between the first and second modules, wherein the first and second modules being longitudinally stacked and are in fluid communication with an inlet and an outlet opposite to the inlet, the cooling apparatus comprising:
a separator installed at a border between the first and second cooling water passages to isolate the first and second cooling water passages such that water introduced through the inlet is branched and flowed through the upper and lower cooling water passages and then is discharged through the outlet.

6. The cooling apparatus of claim 5, wherein the separator is thin plate shaped and has a zigzagged shape, which follows the paths of the cooling water passages.

7. The cooling apparatus of claim 6, wherein a plurality of apertures connecting the upper and lower cooling water passages are formed in the separator to locally enhance cooling efficiency.

8. The cooling apparatus of claim 5, wherein the separator is made of one of a group consisting of a rubber material or stainless steel having corrosion-resistant properties with regards to the cooling water.
